(19) United States
(12) Patent Application Publication
(10) Pub. No.: US 2018/0102746 A1
(43) Pub. Date: Apr. 12, 2018

(54) COOLING APPARATUS, EXHAUST GAS PROCESSING APPARATUS AND CONTROLLING METHOD

(71) Applicant: FUJITSU LIMITED, Kawasaki-shi (JP)

(72) Inventors: TERU NAKANISHI, Isehara (JP); Tatsuya Hirose, Yokohama (JP)

(73) Assignee: FUJITSU LIMITED, Kawasaki-shi (JP)

(21) Appl. No.: 15/722,370

(22) Filed: Oct. 2, 2017

(30) Foreign Application Priority Data
Oct. 11, 2016 (JP) 2016-199682

(51) Int. Cl. H03F 1/30; H03F 3/19; H03F 3/21; H03F 1/02

(52) U.S. Cl. CPC H03F 1/30; H03F 3/19; F01N 3/028; H03F 1/0288; H03F 3/211

(57) ABSTRACT

A cooling apparatus includes a first cooling plate, a second cooling plate provided on the first cooling plate, and a controller that performs, in a normal state, control for supplying coolant to the first cooling plate and performs, in a non-normal state other than the normal state, control for supplying the coolant to the first cooling plate and the second cooling plate.

### CROSS-REFERENCE TO RELATED APPLICATION

This application is based upon and claims the benefit of priority of the prior Japanese Patent Application No. 2016-199682, filed on Oct. 11, 2016, the entire contents of which are incorporated herein by reference.

### FIELD

The embodiments discussed herein are related to a cooling apparatus, an exhaust gas processing apparatus and a controlling method.

### BACKGROUND

Conventionally, an apparatus in which a cooling plate is used is available as a cooling apparatus for cooling electronic parts.

For example, an apparatus is available in which a cooling plate is provided at each of the surface side and the reverse face side of a part mounting board on which electronic parts are mounted. Also, for example, a plate stacking type cooling apparatus is available.

### SUMMARY

According to one aspect of the embodiment, a cooling apparatus includes a first cooling plate, a second cooling plate provided on the first cooling plate, and a controller that performs, in a normal state, control for supplying coolant to the first cooling plate and performs, in a non-normal state other than the normal state, control for supplying the coolant to the first cooling plate and the second cooling plate.

According the one aspect of the embodiment, an exhaust gas processing apparatus includes a microwave generation source that processes fine particles included in exhaust gas, and a cooling apparatus that cools the microwave generation source, wherein the cooling apparatus includes a first cooling plate provided on the microwave generation source, a second cooling plate provided on the first cooling plate, and a controller that performs, in a normal state, control for supplying coolant to the first cooling plate and performs, in a non-normal state other than the normal state, control for supplying the coolant to the first cooling plate and the second cooling plate.

According to the one aspect of the embodiment, a controlling method performed by a controller, includes performing, in a normal state, control for supplying coolant to a first cooling plate, and performing, in a non-normal state other than the normal state, control for supplying the coolant to the first cooling plate and a second cooling plate provided on the first cooling plate.

The object and advantages of the invention will be realized and attained by means of the elements and combinations particularly pointed out in the claims. It is to be understood that both the foregoing general description and the following detailed description are exemplary and explanatory and are not restrictive of the invention.

### BRIEF DESCRIPTION OF DRAWINGS

FIG. 1 is a schematic view depicting a configuration of a cooling apparatus according to an embodiment;

FIG. 2 is a schematic view depicting a configuration of a cooling apparatus and an exhaust gas processing apparatus according to the present embodiment;

FIG. 3 is a schematic view depicting an example of a configuration of a first cooling plate and a second cooling plate provided in the cooling apparatus according to the present embodiment;

FIG. 4 is a schematic view depicting another example of a configuration of the first cooling plate and the second cooling plate provided in the cooling apparatus according to the present embodiment;

FIG. 5 is a flow chart illustrating an example of a controlling method by the cooling apparatus according to the present embodiment;

FIG. 6 is a schematic view depicting an example of a heat insulating structure provided in the cooling apparatus and exhaust gas processing apparatus according to the present embodiment;

FIG. 7 is a view illustrating an effect by the cooling apparatus according to the present embodiment;

FIG. 8 is a schematic view depicting a configuration of a cooling apparatus according to a first modification to the present embodiment;

FIG. 9 is a flow chart illustrating an example of a controlling method for the cooling apparatus according to the first modification to the present embodiment;

FIG. 10 is a schematic view depicting a configuration of a cooling apparatus according to a second modification to the present embodiment; and

FIG. 11 is a flow chart illustrating an example of a controlling method for the cooling apparatus according to the second modification to the present embodiment.

### DESCRIPTION OF PREFERRED EMBODIMENTS

Incidentally, in recent years, development of an exhaust gas processing apparatus that irradiates a microwave on fine particles accumulated in a diesel particulate filter (DPF) for collecting graphite generated in a diesel engine or the like such that the fine particles are burned and regenerated, development of a high-output power transmission amplifier of a microwave for a mobile communication base station or development of a like apparatus is being advanced.

For example, since, in a microwave generation source used for an exhaust gas processing apparatus, an ambient temperature is raised high by heat of exhaust gas, the temperature of the microwave generation source (particularly, a microwave amplifier) sometimes rises higher than a normal temperature. In this case, the state in which the temperature of the microwave generation source is lower than the normal temperature is referred to as normal state, and the state in which the temperature of the microwave generation source is higher than the normal temperature is referred to as non-normal state.

Further, for example, a microwave amplifier used for a high-output power transmission amplifier includes a main amplifier and a peak amplifier, and in the normal state, the main amplifier operates, but in the non-normal state in which sufficient output power cannot be obtained only by the main amplifier, also the peak amplifier operates in addition to the main amplifier.

In such a case as just described, in order to enhance the reliability of the apparatus by making it possible to secure a cooling performance not only in the normal state but also in the non-normal state, it seems recommendable to increase the number of cooling plates to be provided in the cooling apparatus.

However, if cooling is performed by supplying coolant to all cooling plates also in the normal state similarly as in the non-normal state, then cooling is performed excessively in the normal state, and therefore, the power required for supplying of coolant to the cooling plates is wasted.

It is an object of the present embodiment to achieve saving of the power while the reliability of an apparatus is enhanced by making it possible to secure a cooling performance also in the non-normal state.

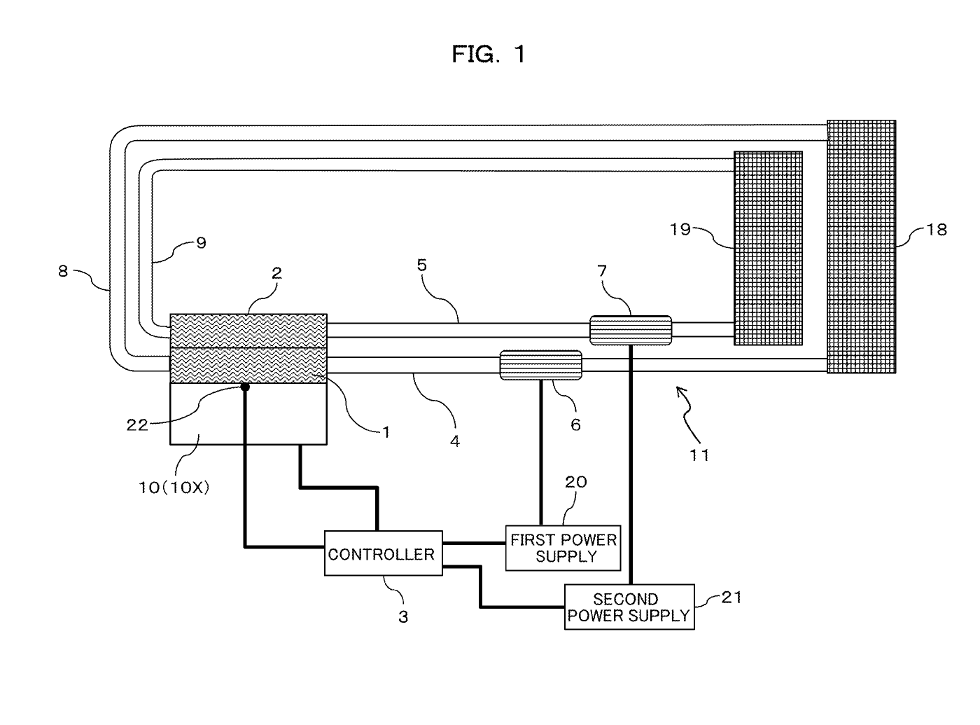

In the following, a cooling apparatus, an exhaust gas processing apparatus and a controlling method according to an embodiment of the present technology are described with reference to FIGS. 1 to 11.

As depicted in FIG. 1, the cooling apparatus according to the present embodiment includes a first cooling plate 1, a second cooling plate 2 provided on the first cooling plate 1 and a controller 3 that performs, in the normal state, control for supplying coolant to the first cooling plate 1 and performs, in the non-normal state other than the normal state, control for supplying coolant to the first cooling plate 1 and the second cooling plate 2.

In the present embodiment, an upper face of the first cooling plate 1 and a lower face of the second cooling plate 2 are joined together.

Here, the controller 3 may decide whether the present state is the normal state or the non-normal state on the basis of the temperature of a cooling target 10 and perform the control in the normal state or the control in the non-normal state on the basis of a result of the decision (for example, refer to FIG. 1).

Further, the cooling apparatus includes a first coolant supply pipe 4 coupled to the first cooling plate 1, a second coolant supply pipe 5 coupled to the second cooling plate 2, a first pump 6 provided on the first coolant supply pipe 4 and a second pump 7 provided on the second coolant supply pipe 5. The controller 3 adjusts, in the normal state, the flow rate of coolant to be supplied to the first cooling plate 1 by controlling the first pump 6 and adjusts, in the non-normal state, the flow rate of coolant to be supplied to the first cooling plate 1 and the second cooling plate 2 by controlling the first pump 6 and the second pump 7 (for example, refer to FIG. 1).

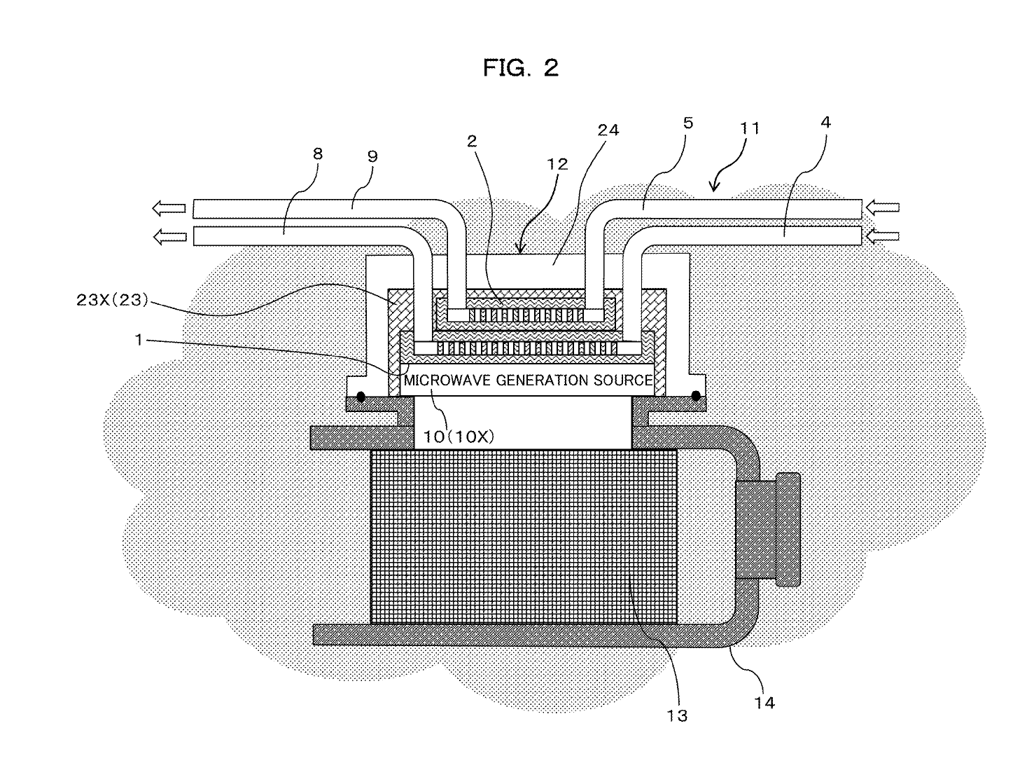

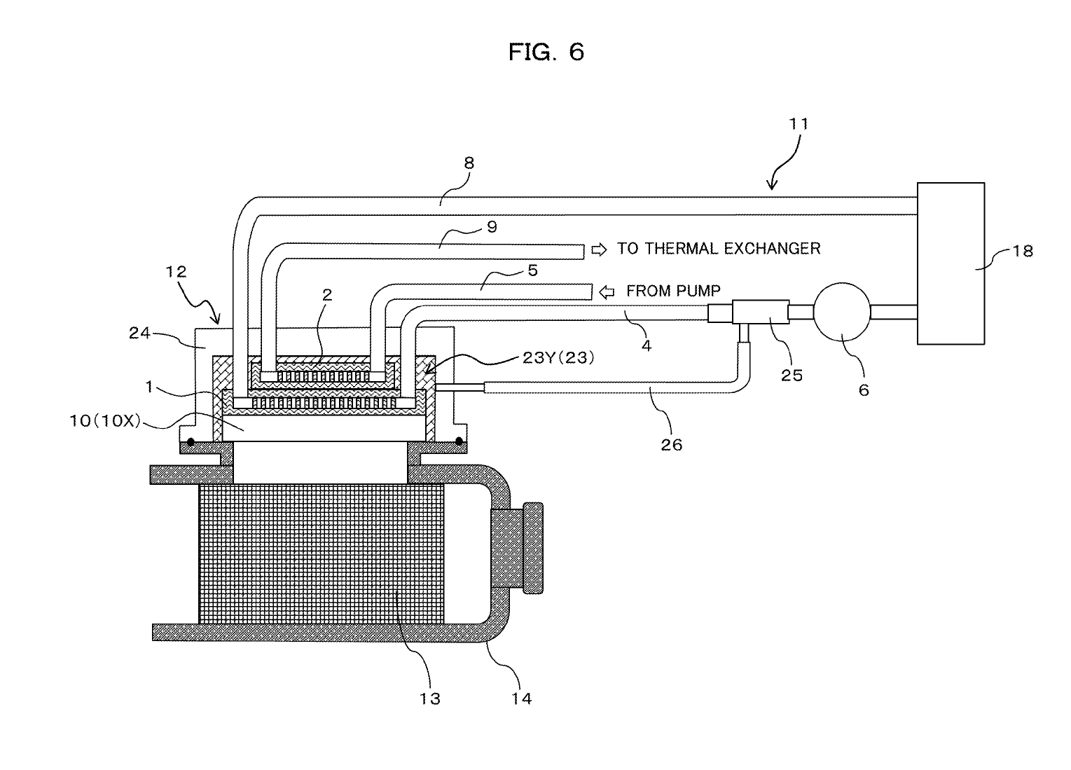

Further, the cooling apparatus may include a heat insulating structure that insulates heat of the first cooling plate 1 and the second cooling plate 2 (for example, refer to FIGS. 2 and 6).

In this case, a heat insulation member that covers the first cooling plate 1 and the second cooling plate 2 may be provided as the heat insulating structure (for example, refer to FIG. 2).

Further, the heat insulating structure is not limited to this, and a vacuum heat insulating structure that places the surroundings of the first cooling plate 1 and the second cooling plate 2 into a vacuum state to insulate heat may be provided as the heat insulating structure (for example, refer to FIG. 6).

Or, the cooling apparatus may include the first coolant supply pipe 4 coupled to the first cooling plate 1, a first coolant discharge pipe 8 coupled to the first cooling plate 1, the second coolant supply pipe 5 coupled to the second cooling plate 2, a second coolant discharge pipe 9 coupled to the second cooling plate 2 and a heat insulating structure that insulates heat of the first coolant supply pipe 4, first coolant discharge pipe 8, second coolant supply pipe 5 and second coolant discharge pipe 9.

In this case, the heat insulating structure may include a heat insulation member that covers the first coolant supply pipe 4, first coolant discharge pipe 8, second coolant supply pipe 5 and second coolant discharge pipe 9.

The heat insulating structure is not limited to this and may otherwise include a vacuum heat insulating structure that places the surroundings of the first coolant supply pipe 4, first coolant discharge pipe 8, second coolant supply pipe 5 and second coolant discharge pipe 9 into a vacuum state to implement heat insulation.

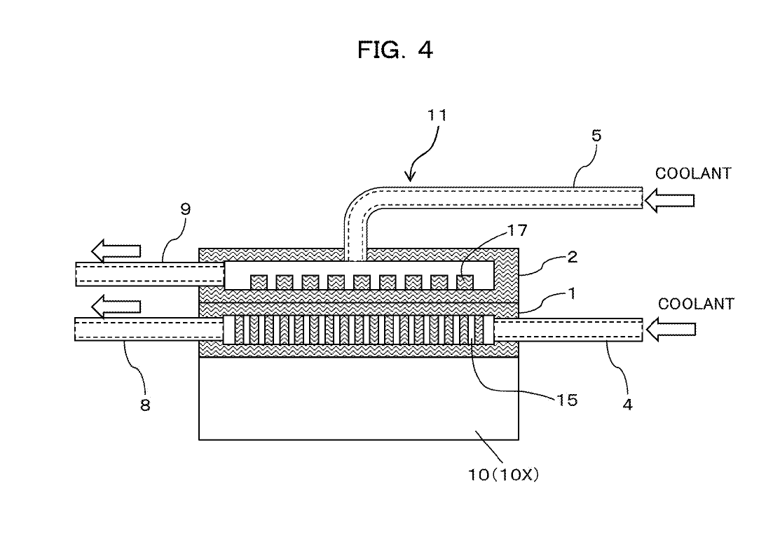

Or, the heat insulating structure may include the first coolant supply pipe 4 coupled to the first cooling plate 1 and the second coolant supply pipe 5 coupled to the second cooling plate 2 are included. Here, the first cooling plate 1 may include a slit-shaped flow path 15 and have the first coolant supply pipe 4 coupled to a side face thereof, and the second cooling plate 2 may include a flow path having columnar projection 17 and have the second coolant supply pipe 5 coupled to an upper face thereof (for example, refer to FIG. 4).

In the cooling apparatus (cooling structure) 11 configured in such a manner as described above, the controller 3 performs, in the normal state, control for supplying coolant to the first cooling plate 1 but performs, in the non-normal state other than the normal state, control for supplying coolant to the first cooling plate 1 and the second cooling plate 2 provided on the first cooling plate 1.

In particular, in the controlling method of the present embodiment, the controller 3 performs, in the normal state, control for supplying coolant to the first cooling plate 1 but performs, in the non-normal state other than the normal state, control for supplying coolant to the first cooling plate 1 and the second cooling plate 2 provided on the first cooling plate 1.

In the following, description is given of, as an example, a case in which the cooling apparatus 11 of the present embodiment is applied to a cooling apparatus that cools a microwave generation source (especially, a microwave amplifier) 10X used in an exhaust gas processing apparatus 12 as depicted in FIG. 2.

In this case, the exhaust gas processing apparatus 12 includes the microwave generation source 10X for processing fine particles included in exhaust gas and the cooling apparatus 11 that cools the microwave generation source 10X.

Here, the microwave generation source 10X includes a microwave amplifier. In particular, the microwave generation source 10X is configured so as to include a microwave amplifier in a metal housing. The cooling apparatus 11 cools the microwave amplifier included in the microwave generation source 10X.

Such an exhaust gas processing apparatus 12 as just described is attached to a location of an exhaust gas purification apparatus (Diesel Particulate Defuser) 14 at which a diesel particulate collection filter 13 is provided such that a microwave is irradiated on fine particles accumulated in the diesel particulate collection filter 13 that collects, for example, soot, PM, graphite and so forth included in gas exhausted from a diesel engine to burn the fine particles.

The cooling apparatus 11 is a cooling apparatus for which a liquid cooling method is used, and, as depicted in FIGS. 1 and 2, the cooling apparatus 11 includes the first cooling plate 1 provided on the microwave generation source 10X, the second cooling plate 2 provided on the first cooling plate 1 and the controller (control unit) 3 that performs, in the normal state, control for supplying coolant to the first cooling plate 1 but performs, in the non-normal state (upon emergency) other than the normal state, control for supplying coolant to the first cooling plate 1 and the second cooling plate 2.

Here, it is decided on the basis of the temperature of the microwave amplifier that is a cooling target whether the present state is the normal state or the non-normal state as hereinafter described. In particular, when the temperature of the microwave amplifier is equal to or lower than a reference set value, it is decided that the present state is the normal state, but when the temperature is higher than the reference set value, it is decided that the present state is the non-normal state. For example, it is decided that, when the microwave amplifier does not operate and when the microwave amplifier operates and the temperature of the microwave amplifier is equal to or lower than the reference set value, the present state is the normal state. On the other hand, when the microwave amplifier operates and the temperature of the microwave amplifier is higher than the reference set value, it is decided that the present state is the non-normal state.

It is to be noted here that, although also the state in which the microwave amplifier does not operate is included in the normal state and cooling by the first cooling plate 1 is performed in this state, this is because, if the engine operates also when the microwave amplifier does not operate, then since the ambient temperature is raised to approximately 100° C. by heat of exhaust gas, and also since the ambient temperature rises in summer or the like, the temperature of the microwave amplifier that is an electronic part is suppressed from becoming high thereby to suppress degradation of the microwave amplifier.

Further, the upper face of the microwave generation source 10X and the lower face (bottom plate) of the first cooling plate 1 are joined together and the upper face (top plate) of the first cooling plate 1 and the lower face (bottom plate) of the second cooling plate 2 are joined together, and the first cooling plate 1 and the second cooling plate 2 are stacked on the microwave generation source 10X.

In this case, the first cooling plate 1 takes the heat from and cools the microwave generation source 10X (especially the microwave amplifier), and the second cooling plate 2 takes the heat from and cools the first cooling plate 1.

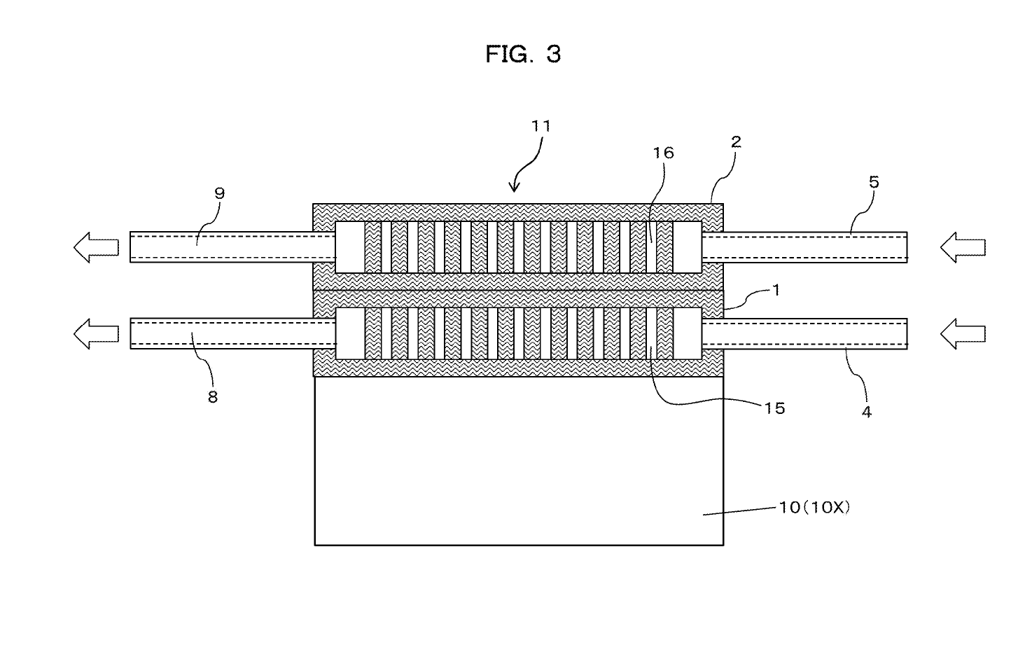

Further, in the inside of the first cooling plate 1 and the second cooling plate 2, slit-shaped flow paths 15 and 16 or a flow path having the columnar projections 17 is formed such that the bottom plate and the top plate are thermally coupled to each other, for example, as depicted in FIGS. 3 and 4.

Further, the cooling apparatus includes the first coolant supply pipe 4 coupled to the first cooling plate 1, first coolant discharge pipe 8 coupled to the first cooling plate 1, second coolant supply pipe 5 coupled to the second cooling plate 2, and second coolant discharge pipe 9 coupled to the second cooling plate 2. Here, each of the first coolant supply pipe 4, first coolant discharge pipe 8, second coolant supply pipe 5 and second coolant discharge pipe 9 is a metal pipe, for example, configured from copper, copper alloy, aluminum, aluminum alloy, stainless steel material or the like.

Here, as depicted in FIG. 1, the other ends of the first coolant supply pipe 4 and the first coolant discharge pipe 8 are coupled to a first heat exchanger 18, and the other ends of the second coolant supply pipe 5 and the second coolant discharge pipe 9 are coupled to a second heat exchanger 19.

Further, here, as depicted in FIG. 3, the first cooling plate 1 includes the slit-shaped flow path 15 and the first coolant supply pipe 4 and the first coolant discharge pipe 8 are coupled to side faces thereof. Further, the second cooling plate 2 includes the slit-shaped flow path 16 and the second coolant supply pipe 5 and the second coolant discharge pipe 9 are coupled to the side faces thereof.

It is to be noted that, as depicted in FIG. 4, the first cooling plate 1 may include the slit-shaped flow path 15 and the first coolant supply pipe 4 may be coupled to a side face thereof, and the second cooling plate 2 may include a flow path having the columnar projections 17 and the second coolant supply pipe 5 may be coupled to an upper face thereof. Consequently, effective cooling can be performed for a hot spot.

Further, as depicted in FIG. 1, the cooling apparatus includes the first pump 6 provided on the first coolant supply pipe 4 and the second pump 7 provided on the second coolant supply pipe 5.

The controller 3 controls, in the normal state, the first pump 6 to adjust the flow rate of coolant to be supplied to the first cooling plate 1 but controls, in the non-normal state, the first pump 6 and the second pump 7 to adjust the flow rate of coolant to be supplied to the first cooling plate 1 and the second cooling plate 2.

Here, the controller 3 controls the first pump 6 by controlling a first power supply 20 coupled to the first pump 6, and controls the second pump 7 by controlling a second power supply 21 coupled to the second pump 7.

In this manner, the first coolant supply pipe 4 and first coolant discharge pipe 8 and the second coolant supply pipe 5 and second coolant discharge pipe 9 are attached to the first cooling plate 1 and the second cooling plate 2, respectively, such that the flow rate of coolant to flow through the pipes 4, 5, 8 and 9 can be individually adjusted. Further, the first cooling plate 1 and the second cooling plate 2 can adjust the flow rate independently of each other using the individual pumps 6 and 7.

Here, the cooling apparatus includes a temperature measurement unit 22 provided in the microwave amplifier that is provided in the microwave generation source 10X as the cooling target 10.

Here, the temperature measurement unit 22 is, for example, a temperature sensor, a thermocouple, an infrared ray sensor or the like.

The controller 3 decides whether the present state is the normal state or the non-normal state on the basis of the temperature of the microwave amplifier measured by the temperature measurement unit 22, and performs control in the normal state or control in the non-normal state on the basis of a result of the decision.

In this manner, the controller 3 decides whether the present state is the normal state or the non-normal state on the basis of the temperature of the cooling target 10 and performs control in the normal state or control in the non-normal state on the basis of a result of the decision. In short, flow rate adjustment of the first cooling plate 1 and the second cooling plate 2 is performed by monitoring the temperature of the cooling target 10.

It is to be noted here that the controller 3 performs also control of the microwave amplifier (microwave generation source 10X).

Now, a controlling method for the cooling apparatus 11 including such a controlling system as described above is described.

In the present embodiment, the controller 3 performs, in the normal state, control for supplying coolant to the first cooling plate 1 but performs, in the non-normal state other than the normal state, control for supplying coolant to the first cooling plate 1 and the second cooling plate 2 that is provided on the first cooling plate 1.

In particular, such control as described below is performed.

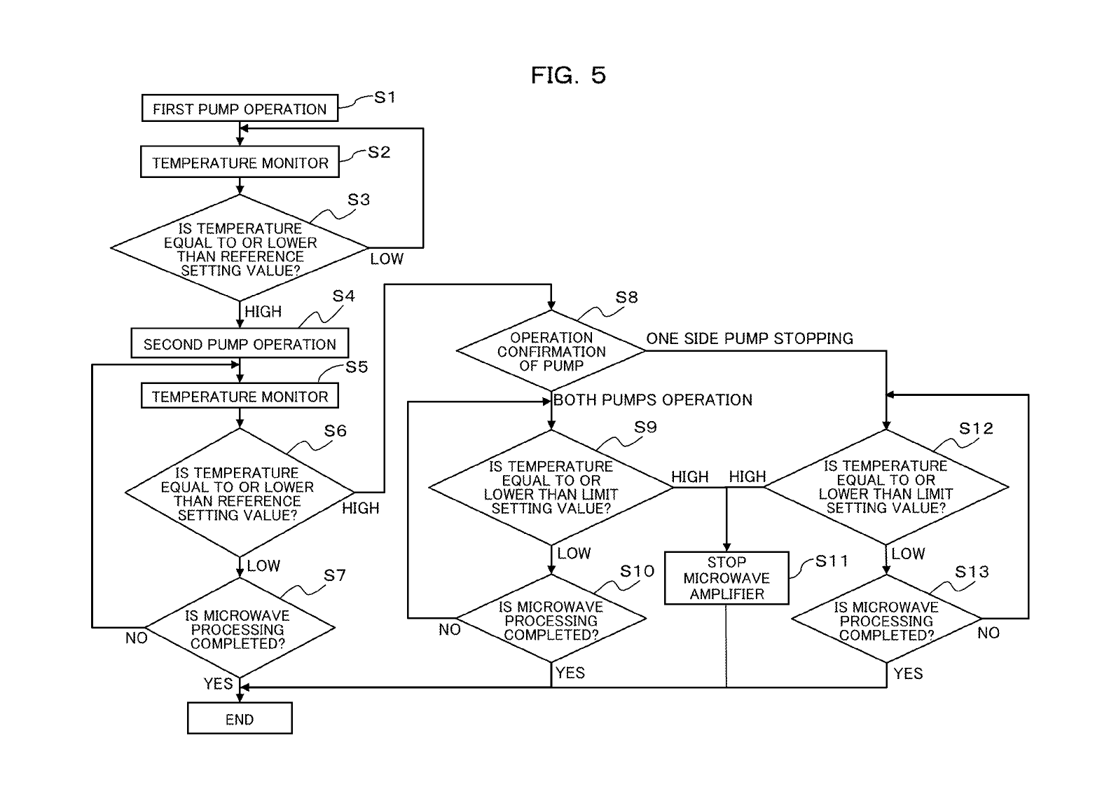

As depicted in FIG. 5, in the normal state, namely, in normal operation, the controller 3 performs control for operating the first pump 6 in an interlocking relationship with operation of the microwave amplifier included in the microwave generation source 10X (step S1).

In particular, when the microwave amplifier is rendered operative, the controller 3 controls the first power supply 20 to render the first pump 6 operative in an interlocking relationship with the operation of the microwave amplifier.

Consequently, coolant circulates through the first coolant supply pipe 4, first cooling plate 1, first coolant discharge pipe 8 and first heat exchanger 18 to perform cooling of the microwave amplifier (microwave generation source 10X) only by the first cooling plate 1 (refer to FIG. 1).

The controller 3 performs control of the entire cooling system while monitoring the temperature measured by the temperature measurement unit (temperature sensor) 22 built in the microwave amplifier (steps S2 to step S13).

In particular, the controller 3 first fetches the temperature measured by the temperature measurement unit 22 (step S2), and decides whether or not the fetched temperature (value of the temperature sensor) is equal to or lower than a reference set value determined in advance (step S3).

Here, the reference set value is set to a temperature suitable for operation of the microwave amplifier. If operation of the microwave amplifier is continued in a state in which the temperature exceeds the reference set value, then this has an influence on the life of the microwave amplifier.

If it is decided as a result of the decision that the temperature is equal to or lower than the reference set value, then the processing advances to the LOW route and the controller 3 continues the control for operating the first pump 6 while monitoring the temperature.

On the other hand, if it is decided that the temperature exceeds the reference set value, then the processing advances to the HIGH route and the controller 3 performs control for operating the second pump 7 (step S4). In short, the controller 3 controls the second power supply 21 to operate the second pump 7.

Consequently, the coolant circulates through the second coolant supply pipe 5, second cooling plate 2, second coolant discharge pipe 9 and second heat exchanger 19 such that cooling of the microwave amplifier (microwave generation source 10X) is performed not only by the first cooling plate 1 but also by the second cooling plate 2 (refer to FIG. 1).

Then, the controller 3 fetches the temperature measured by the temperature measurement unit 22 (step S5), and decides whether or not the temperature (value of the temperature sensor) is equal to or lower than the reference set value determined in advance (step S6).

If it is decided as a result of the decision that the temperature is equal to or lower than the reference set value, then the processing advances to the LOW route and the controller 3 continues the control for operating the second pump 7 while monitoring the temperature until the process by the microwave is completed. Then, if it is decided at step S7 that the process by the microwave is completed, then the control is ended.

On the other hand, if it is decided that the temperature exceeds the reference set value, namely, if the temperature measured by the temperature measurement unit 22 is not equal to or lower than the reference set value even if the second pump 7 is operated, then the processing advances to the HIGH route and the controller 3 confirms an operation situation of the first pump 6 and the second pump 7 (step S8).

Here, the confirmation of the operation situation of the first pump 6 and the second pump 7 is performed by monitoring, for example, the speed of rotation, voltage, current and or the like.

If it is decided as a result of the decision that both of the pumps 6 and 7 operate (are in operation), then it is considered that the cooling performance is in a limit state. Therefore, the controller 3 decides whether or not the current temperature is equal to or lower than a limit set value (step S9). If it is decided that the temperature is equal to or lower than the limit set value, namely, if it is decided that the temperature does not exceed the limit set value, then the processing advances to the LOW route and the controller 3 continues the control until the process by a microwave is completed. Then, if it is decided at step S10 that the process by the microwave is completed, then the control is ended. Here, the limit set value is set to a limit temperature of the microwave amplifier.

On the other hand, if it is decided at step S9 that the temperature is not equal to or lower than the limit setting value, namely, if it is decided that the temperature exceeds the limit set value, then the processing advances to the HIGH route and the controller 3 stops the microwave amplifier (step S11) and ends the control.

Incidentally, if it is decided that, as a result when the operation situation of the first pump 6 and the second pump 7 is confirmed, such operation failure that one of the pumps is stopping occurs, then the controller 3 decides whether or not the current temperature is equal to or lower than the limit set value (step S12). Then, if it is decided that the present temperature is equal to or lower than the limit set value, namely, if it is decided that the current temperature does not exceed the limit set value, then the processing advances to the LOW route and the controller 3 continues the control until the processing by the microwave is completed. Then, if it is decided at step S13 that the processing by the microwave is completed, then the control is ended.

On the other hand, if it is decided at step S12 that the current temperature is not equal to or lower than the limit setting value, namely, if it is decided that the current temperature exceeds the limit set value, then the processing advances to the HIGH route and the controller 3 stops the microwave amplifier (step S11) and ends the control.

Incidentally, since the exhaust gas processing apparatus 12 is attached to the exhaust gas purification apparatus 14 (refer to FIG. 2), the ambient temperature becomes, for example, approximately 100° C. by heat of exhaust gas. Further, the ambient temperature sometimes increases in summer or the like.

Therefore, in order to reduce the influence of the ambient temperature, the cooling apparatus includes a heat insulating structure 23 that insulates heat of the first cooling plate 1 and the second cooling plate 2 as depicted in FIG. 2. Consequently, the cooling apparatus can reduce heat to be received from the surroundings that is at a high temperature and suppress degradation of the cooling performance thereby to assure the cooling performance.

In this case, the cooling apparatus may include, as the heat insulating structure 23, a heat insulation material 23X that covers the first cooling plate 1 and the second cooling plate 2.

Here, also the microwave generation source 10X is covered with the heat insulation material 23X. In particular, the microwave generation source 10X, first cooling plate 1 and second cooling plate 2 are covered with the heat insulation material 23X. Further, the components just mentioned are covered with a cover 24 (for example, a metal cover formed from stainless steel), and the cover 24 is attached to the exhaust gas purification apparatus 14.

Here, as the heat insulation material 23X, a material capable of insulating external heat such as, for example, a fiber type material such as glass wool or sheep wool or a foamed resin type material such as a rigid urethane foam material or a phenol foam material may be used.

Further, where it is demanded to enhance the heat insulation performance, the cooling apparatus may include, as the heat insulating structure 23, a vacuum heat insulating structure 23Y that places the surroundings of the first cooling plate 1 and the second cooling plate 2 into a vacuum state to achieve heat insulation, for example, as depicted in FIG. 6. It is to be noted that, in FIG. 6, a pattern is applied to portions that form the vacuum heat insulating structure 23Y in order to facilitate recognition of the portions.

Here, also heat of the microwave generation source 10X is insulated by the vacuum heat insulating structure 23Y.

In this case, the cover 24 may be provided so as to cover the microwave generation source 10X, first cooling plate 1 and second cooling plate 2, and the inside thereof may be placed into a vacuum state to configure the vacuum heat insulating structure 23Y.

For example, the inside of the cover 24, namely, the portion that serves as the vacuum heat insulating structure 23Y around the microwave generation source 10X, first cooling plate 1 and second cooling plate 2, may be evacuated such that the vacuum state is maintained by pinch off of a pipe portion provided at an evacuation port.

Further, the cooling apparatus may be configured such that, for example, as depicted in FIG. 6, an aspirator or ejector 25 is provided at the coolant supplying pipe 4 between the first cooling plate 1 and the first pump 6 and one end of a decompression pipe 26 is attached to a decompression port of the aspirator or ejector 25 while the other end of the decompression pipe 26 is attached to a vacuum port of the cover 24 such that the aspirator or ejector 25 is operated utilizing water cooling type coolant to evacuate the portion that serves as the vacuum heat insulating structure 23Y coupled through the decompression pipe 26 to the decompression port decompressed by a Venturi effect at a central location whereas the vacuum state is maintained usually during pump operation.

Further, the cooling apparatus may include a heat insulating structure that insulates heat of the first coolant supplying pipe 4, first coolant discharging pipe 8, second coolant supplying pipe 5 and second coolant discharging pipe 9. In particular, the first coolant supplying pipe 4, first coolant discharging pipe 8, second coolant supplying pipe 5 and second coolant discharging pipe 9 may be configured as heat insulating pipes. By this, heat to be received from the surroundings that is in a high temperature can be reduced and degradation of the cooling performance can be suppressed thereby to secure the cooling performance.

For example, a metal pipe that has a wall of a double structure (double pipe structure) and is vacuum in the inside thereof may be used for the first coolant supplying pipe 4, first coolant discharging pipe 8, second coolant supplying pipe 5 and second coolant discharging pipe 9. In this case, as a heat insulating structure, the first coolant supplying pipe 4, first coolant discharging pipe 8, second coolant supplying pipe 5 and second coolant discharging pipe 9 include a vacuum heat insulating structure.

Further, for example, the outside of the metal pipe (one-layer pipe formed from a metal material) configuring the first coolant supplying pipe 4, first coolant discharging pipe 8, second coolant supplying pipe 5 and second coolant discharging pipe 9 may be covered with a heat insulation material. In this case, as the heat insulating structure, the heat insulation material covering the first coolant supplying pipe 4, first coolant discharging pipe 8, second coolant supplying pipe 5 and second coolant discharging pipe 9 is provided. It is to be noted that, as the heat insulation material, a heat insulation material similar to the heat insulation material that covers the first cooling plates 1 and 2 described above may be used.

Incidentally, as described hereinabove, the cooling plate provided in the cooling apparatus for which a liquid cooling type pump for forced circulation is used is structured such that the second cooling plate 2 is mounted on the first cooling plate 1, in which the bottom plate and the top plate are thermally coupled to each other, such that the first cooling plate 1 and the second cooling plate 2 can be controlled independently of each other.

Consequently, while, in the normal state, cooling is performed by the first cooling plate 1, if it is predicted that the cooling performance becomes insufficient from an influence of the ambient temperature or the like (in the non-normal state), then the second cooling plate 2 operates in addition to the first cooling plate 1 to assist the cooling performance thereby to allow suppression of degradation of the cooling performance.

In this manner, the first cooling plate 1 and the second cooling plate 2 are stacked such that the flow rate of the two cooling plates 1 and 2 can be adjusted independently of each other, and in the normal state, only the first cooling plate 1 is used, but in the non-normal state, also the second cooling plate 2 is used in addition to the first cooling plate 1.

Consequently, while reduction of the space is achieved in that a large area is not required, and also in the non-normal state, the cooling performance is secured to enhance the reliability of the apparatus, and besides reduction of the power can be achieved, for example, in comparison with that in an alternative case in which two cooling plates are used usually.

Further, by applying such a configuration as described above, cooling can be performed by the second cooling plate 2 also when malfunction of the first cooling plate 1 occurs, and a suddenly rise of the temperature can be suppressed.

Therefore, the redundancy can be provided by continuing cooling by the second cooling plate 2 until maintenance of the first cooling plate 1 is performed.

It is to be noted that, while the embodiment is described above taking, as an example, a case in which the two cooling plates 1 and 2 are used, the number of cooling plates is not limited to this and two or more cooling plates may be used.

In this case, it is preferable to apply such a structure that, in the cooling plate or plates other than the cooling plate positioned at the uppermost side, the bottom plate and the top plate are thermally coupled to each other and the cooling plate positioned at the uppermost side is supplied with coolant from an upper location at the center as in the case of jet cooling. Consequently, effective cooling can be performed for a hot spot.

In particular, such a configuration may be applied that, where the size (magnitude) of the microwave generation source 10X including the microwave amplifier is approximately 60 mm×approximately 60 mm, the first cooling plate 1 has a size of approximately 80 mm×approximately 60 mm and is configured such that the slip-shaped flow path 15 is provided on the bottom plate and the bottom plate is brazed or welded to the top plate while the second cooling plate 2 has a size of approximately 60 mm×approximately 60 mm and is configured such that columnar projections 17 each having a size of approximately 1 mm×approximately 1 mm and a height of approximately 3 mm are provided at distances of approximately 0.5 mm in a grid pattern on the bottom plate and the bottom plate is blazed or welded to the top plate.

Meanwhile, for the material of the first cooling plate 1 and the second cooling plate 2, oxygen free copper may be used.

Further, for the coolant for liquid cooling, pure water may be used and supplied at a flow rate of approximately 0.8 L per minute by the circulation pumps 6 and 7.

Further, for the heat exchangers 18 and 19, a radiator of the corrugated fin type may be used.

Further, grease material that is good in heat conduction may be interposed on each of interfaces of the microwave generation source 10X including the microwave amplifier, first cooling plate 1 and second cooling plate 2 to couple them to each other.

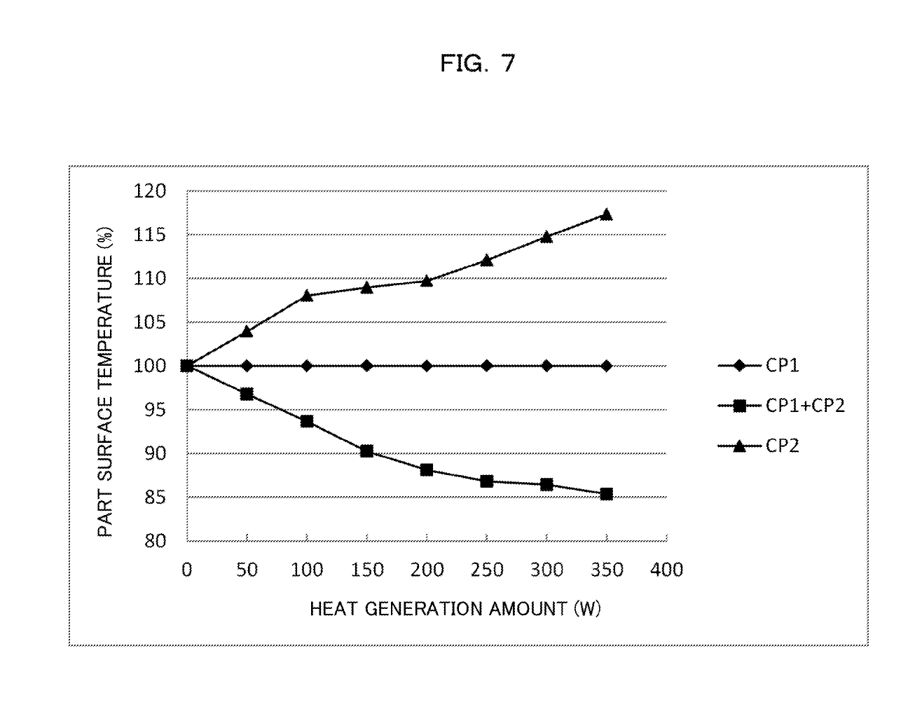

When the surface temperature (part surface temperature) of the microwave amplifier was measured using the cooling apparatus 11 according to such a particular configuration example as described above by causing the cooling plates 1 and 2 in accordance with three conditions given below while changing the heat generation amount of the microwave amplifier included in the microwave generation source 10X, such results as depicted in FIG. 7 were obtained.

Here, the surface temperature was measured by changing the heat generation amount of the microwave amplifier in accordance with the three conditions that only the first cooling plate 1 was operated (CP1), that the second cooling plate 2 was operated in addition to the first cooling plate 1 (CP1+CP2) and that only the second cooling plate 2 was operated (CP2).

In FIG. 7, the surface temperature when only the first cooling plate 1 was operated for cooling (CP1) is indicated as 100%.

As depicted in FIG. 7, when the second cooling plate 2 is operated in addition to the first cooling plate 1 to perform cooling (CP1+CP2), it can be recognized that the surface temperature of the microwave amplifier becomes lower than 100% and the cooling performance is improved.

On the other hand, when only the second cooling plate 2 is operated for cooling (CP2), since the second cooling plate 2 is provided at the side far from the microwave amplifier (namely, since the second cooling plate 2 is attached to the microwave amplifier with the first cooling plate 1 interposed therebetween), although there is the tendency that the surface temperature of the microwave amplifier becomes high, also it can be confirmed that, at the individual heat generation amounts, the microwave amplifier is kept at a fixed temperature and has redundancy.

Incidentally, the reason why such a configuration as described above is used is such as follows.

In recent years, development of a high output power transmission amplifier of a microwave for a mobile communication base station, development of an apparatus that irradiates a microwave upon fine particles accumulated in a diesel particulate collection filter for collecting graphite and so forth generated by a diesel engine to burn and regenerate the fine particles and so forth are advancing, and an amplifier for a microwave is utilized in various fields.

Although high output power can be obtained by amplifying a microwave by a high-performance amplifier, the heat generation amount of the devices increases together with this, and cooling of the devices is becoming significant to achieve a stabilized performance and a longer life.

For example, a microwave generator includes a circuit for amplifying a microwave in order to obtain high output power (microwave amplifier), and if a microwave is oscillated in the form of a continuous wave (CW) from the microwave amplifier, then the temperature of the part itself rises, resulting in reduction of the part life. On the other hand, when the cooling performance is poor, there is the possibility that the part itself may be broken.

Therefore, it is significant to perform effective cooling in various utilization scenes so as to suppress an unnecessary rise of the temperature of the microwave amplifier.

For example, the temperature around a diesel particulate collection filter of a diesel engine is a high temperature, and since the cooling plate receives heat also from the surroundings, it is significant to cool the diesel particulate collection filter with an increased power efficiency for a demanded cooling performance by limited power supply in a limited space.

Further, under such a situation that the cooling system is likely to suddenly enter an operation stop state, for example, by failure of a pump or clogging of garbage in a piping, in order to suppress failure of parts, also it is significant to cause the microwave amplifier to operate with redundancy (or life prolongation).

Therefore, such a configuration as described above is adopted.

Accordingly, the cooling apparatus, exhaust gas processing apparatus and controlling method according to the present embodiment exhibit an advantageous effect that power saving can be achieved while the reliability of the apparatus is enhanced by making it possible to secure a cooling performance also in a non-normal state.

It is to be noted that, while in the embodiment described above, the cooling apparatus includes the first pump 6 provided on the first coolant supply pipe 4 and the second pump 7 provided on the second coolant supply pipe 5 and is configured such that the controller 3 controls, in the normal state, the first pump 6 to adjust the flow rate of coolant to be supplied to the first cooling plate 1 but controls, in the non-normal state, the first pump 6 and the second pump 7 to adjust the flow rate of coolant to be supplied to the first cooling plate 1 and the second cooling plate 2, the cooling apparatus is not limited to this.

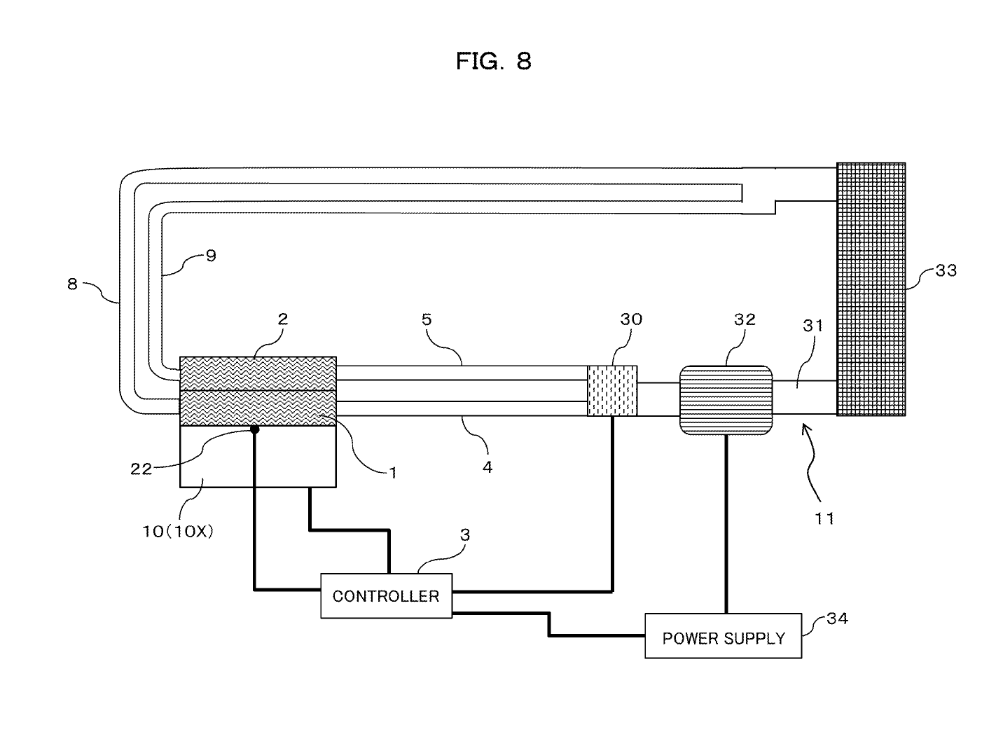

For example, the microwave amplifier may include, as depicted in FIG. 8, a flow rate adjuster 30 coupled to the first coolant supply pipe 4 and the second coolant supply pipe 5, a third coolant supply pipe 31 coupled to the flow rate adjuster 30, and a pump 32 provided on the third coolant supply pipe 31 and is configured such that the controller 3 controls, in the normal state, the pump 32 and the flow rate adjuster 30 to adjust the flow rate of coolant to be supplied to the first cooling plate 1 but controls, in the non-normal state, the pump 32 and the flow rate adjuster 30 to adjust the flow rate of coolant to be supplied to the first cooling plate 1 and the second cooling plate 2. The microwave amplifier just described is hereinafter referred to as first modification.

In this case, the flow rate of the first cooling plate 1 and the second cooling plate 2 can be adjusted independently of each other using the single pump 32 and using the flow rate adjuster 30. In this manner, the two cooling plates 1 and 2 can be controlled independently of each other using a single pump.

In particular, the first coolant supply pipe 4 coupled to the first cooling plate 1 and the second coolant supply pipe 5 coupled to the second cooling plate 2 may be coupled to a heat exchanger 33 through the flow rate adjuster 30 and the third coolant supply pipe 31, and the pump 32 may be provided at the third coolant supply pipe 31.

The flow rate adjuster 30 may be provided at the downstream side of the pump 32 in this manner such that the flow rate to be supplied to each of the first cooling plate 1 side and the second cooling plate 2 side can be adjusted.

In this case, the controller 3 may be coupled to the flow rate adjuster 30 and a power supply 34 coupled to the pump 32 such that the flow rate adjuster 30 and the pump 32 are controlled by the controller 3 to adjust the flow rate of coolant to be supplied to the first cooling plate 1 and the second cooling plate 2.

It is to be noted that, in this case, since the single heat exchanger 33 may be used, the first coolant discharge pipe 8 coupled to the first cooling plate 1 and the second coolant discharge pipe 9 coupled to the second cooling plate 2 may be joined together and coupled to the heat exchanger 33.

Where the cooling apparatus 11 is configured in this manner, the controlling method may be such as follows.

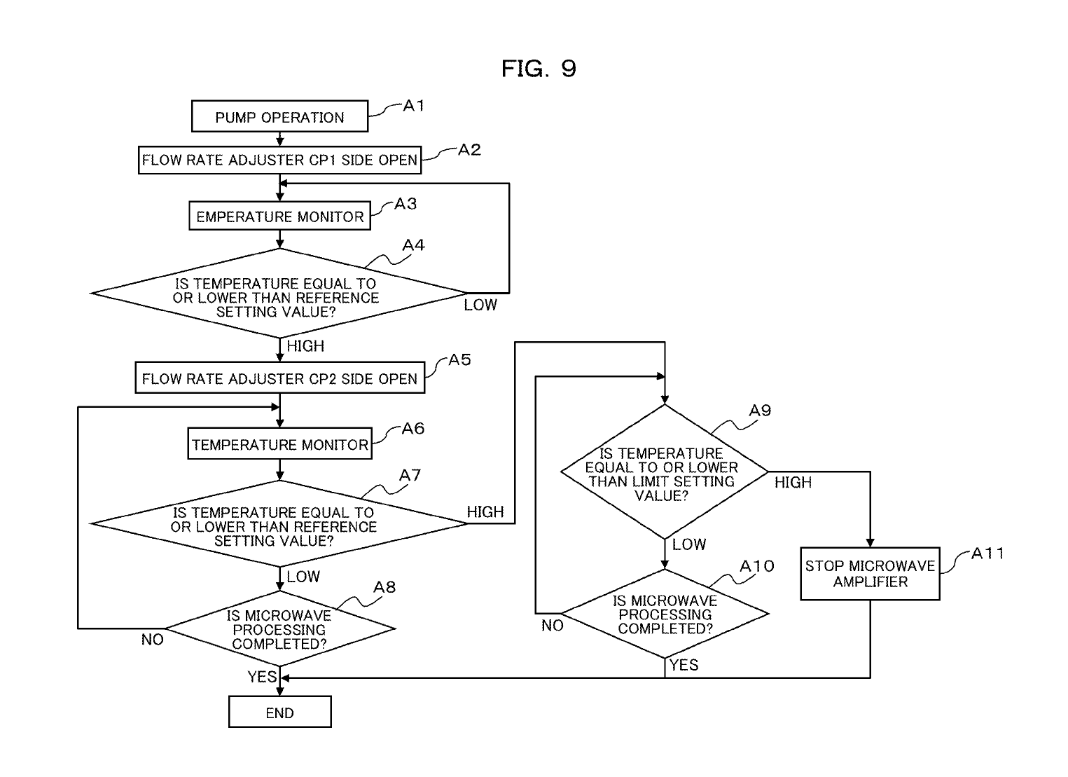

As depicted in FIG. 9, in the normal state, namely, in normal operation, the controller 3 performs control for operating the pump 32 in an interlocking relationship with operation of the microwave amplifier included in the microwave generation source 10X (step A1) and further performs control for placing the first cooling plate 1 side of the flow rate adjuster 30 into an open state (step A2).

In particular, when the controller 3 renders the microwave amplifier included in the microwave generation source 10X operative, it controls the power supply 34 in an interlocking relationship with the operation to render the pump 32 operative and places the first cooling plate 1 side of the flow rate adjuster 30 into an open state.

Consequently, the coolant flows only to the first cooling plate 1 side and circulates through the third coolant supply pipe 31, first coolant supply pipe 4, first cooling plate 1, first coolant discharge pipe 8 and heat exchanger 33. Consequently, cooling of the microwave amplifier (microwave generation source 10X) is performed by the first cooling plate 1 (refer to FIG. 8).

Then, while the controller 3 monitors the temperature measured by the temperature measurement unit (temperature sensor) 22 built in the microwave amplifier, it performs control of the entire cooling system (step A3 to step A11).

In particular, the controller 3 first fetches the temperature measured by the temperature measurement unit 22 (step A3) and decides whether or not the temperature (value of the temperature sensor) is equal to or lower than a reference set value determined in advance (step A4).

Here, the reference set value is set to a temperature suitable for operating the microwave amplifier. If operation of the microwave amplifier is continued in a state in which the reference set value is exceeded, then this has an influence on the life of the microwave amplifier.

If it is decided as a result of the decision that the temperature is equal to or lower than the reference set value, then the processing advances to the LOW route and the controller 3 continues the control for operating the controller 3 while monitoring the temperature and the control for placing the first cooling plate 1 side of the flow rate adjuster 30 into an open state.

On the other hand, if it is decided that the reference set value is exceeded, then the processing advances to the HIGH route and the controller 3 performs the control for placing also the second cooling plate 2 side into an open state in addition to the first cooling plate 1 side of the flow rate adjuster 30 (step A5).

Consequently, the coolant flows also to the second cooling plate 2 side, and the coolant flows also through the second coolant supply pipe 5, second cooling plate 2 and second coolant discharge pipe 9. Consequently, cooling of the microwave amplifier (microwave generation source 10X) is performed also by the second cooling plate 2 in addition to the first cooling plate 1.

Then, the controller 3 fetches the temperature measured by the temperature measurement unit 22 (step A6) and decides whether or not the temperature (value of the temperature sensor) is equal to or lower than the reference set value determined in advance (step A7).

If it is decided as a result of the decision that the temperature is equal to or lower than the reference set value, then the processing advances to the LOW route and the controller 3 continues the control for placing also the second cooling plate 2 side of the flow rate adjuster 30 into an open state while monitoring the temperature until the process by a microwave is completed. Then, if it is decided that the processing by a microwave is completed, then the controller 3 ends the control.

On the other hand, if it is decided that the reference set value is exceeded, namely, even if the temperature measured by the temperature measurement unit 22 does not become equal to or lower than the reference set value even if the coolant is supplied also to the second cooling plate 2 side, since it is considered that the cooling apparatus is operating at the limit of the processing capacity thereof, the processing advances to the HIGH route and the controller 3 decides whether or not the current temperature is equal to or lower than a limit set value (step A9). If it is decided that the temperature at the time is equal to or lower than the limit set value, namely, if the limit set value is not exceeded, then the processing advances to the LOW route and the controller 3 continues the control until the processing by a microwave is completed. Then, if it is decided at step A10 that the processing by a microwave is completed, then the controller 3 ends the process. Here, the limit set value is set to a limit temperature of the microwave amplifier.

On the other hand, if it is decided at step A9 that the current temperature is not equal to or lower than the limit set value, namely, if it is decided that the limit set value is exceeded, then the processing advances to the HIGH route and the controller 3 stops the microwave amplifier (step A11), whereafter it ends the control.

Incidentally, although the embodiment and the first modification described hereinabove are described taking a case in which the present technology is applied to the cooling apparatus 11 for cooling the microwave generation source 10X (especially the microwave amplifier) used in the exhaust gas processing apparatus 12 as an example, the present technology is not limited to this. For example, also it is possible to apply the present technology to apply a cooling apparatus for cooling a microwave amplifier that is used in a high-output power transmission amplifier of a microwave for a base station. This is referred to as second modification.

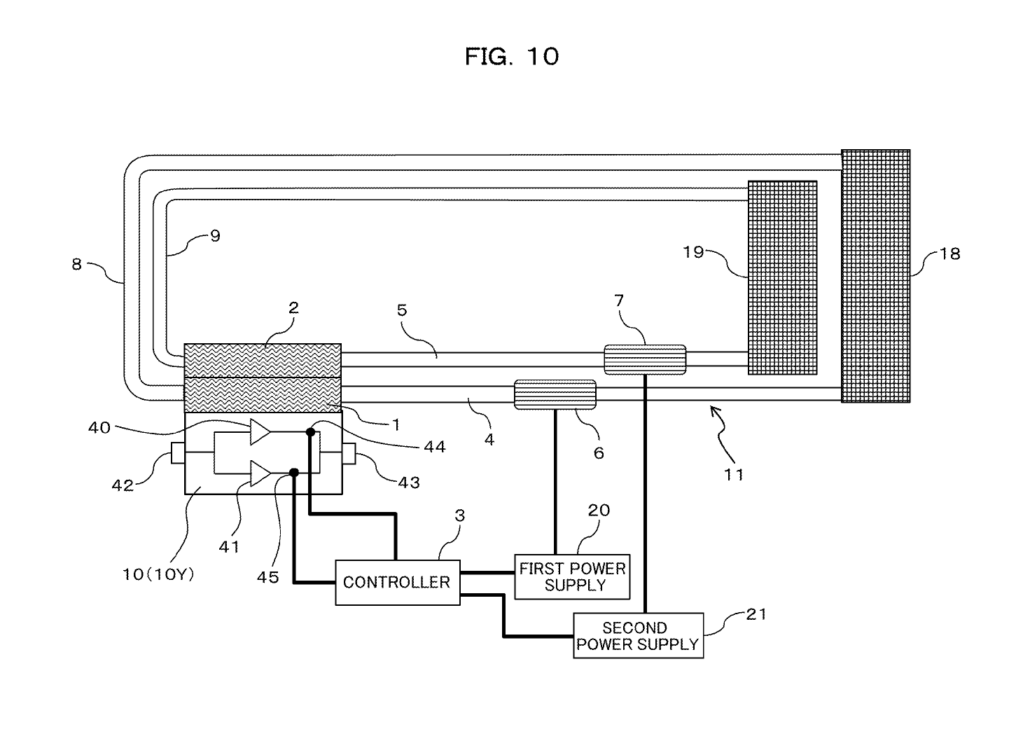

In this case, the controller 3 may decide on the basis of an output signal of the cooling target 10 whether or not the current state is the normal state or the non-normal state and perform control in the normal state or control in the non-normal state on the basis of a result of the decision (refer to FIG. 10).

In other words, the controller 3 may detect the output power (output signal) of a microwave signal of the microwave amplifier 10X that is the cooling target 10 and adjust, in the normal state or in the non-normal state, the flow rate of coolant to be supplied to the first cooling plate 1 and the second cooling plate 2 (refer to FIG. 10).

It is to be noted that, similarly as in the case of the embodiment and the first modification described above, the controller 3 may decide on the basis of the temperature of the cooling target 10 whether or not the current state is the normal state or the non-normal state and perform control in the normal state or control in the non-normal state on the basis of a result of the decision.

In this manner, where the present technology is applied to the cooling apparatus 11 that cools the microwave amplifier 10Y that is used in a high-output power amplifier of a microwave for a base station (refer to FIG. 10), an electronic apparatus includes the microwave amplifier 10Y and the cooling apparatus 11 for cooling the microwave amplifier 10Y, and the cooling apparatus 11 includes the first cooling plate 1 provided on the microwave amplifier 10Y, the second cooling plate 2 provided on the first cooling plate 1 and the controller 3 that performs, in the normal state, control for supplying coolant to the first cooling plate 1 but performs, in the non-normal state other than the normal state, control for supplying coolant to the first cooling plate 1 and the second cooling plate 2.

Further, the microwave amplifier 10Y may include a first amplifier 40 and a peak amplifier 41 coupled in parallel to the first amplifier 40 and may be configured such that the controller 3 decides on the basis of an output signal of the peak amplifier 41 provided in the microwave amplifier 10Y whether or not the current state is the normal state or the non-normal state and performs control in the normal state or control in the non-normal state on the basis of a result of the decision (refer to FIG. 10).

In particular, as the microwave amplifier 10Y used in a high output power transmission amplifier of a microwave for a base station, a Doherty amplifier for microwave transmission for a base station is sometimes provided.

Here, as depicted in FIG. 10, in the Doherty amplifier 10Y, the main amplifier (first amplifier) 40 and the peak amplifier (second amplifier) 41 are coupled in parallel and mounted in an amplifier housing. It is to be noted that reference numeral 42 in FIG. 10 denotes a signal input terminal (coaxial connector), and reference numeral 43 denotes a signal output terminal (coaxial connector).

Thus, in the Doherty amplifier 10Y, the main amplifier 40 begins to operate first, and the main amplifier 40 operates in a maximum efficiency. Then, if the input is further increased, then the peak amplifier 41 operates, and finally, saturation output power equal to twice that of a single amplifier can be obtained by both of the amplifiers 40 and 41.

Where such a Doherty amplifier 10Y as described above is cooled by the cooling apparatus 11 configured in such a manner as in the embodiment described hereinabove, in place of providing the temperature measurement unit such that control is performed on the basis of a temperature, output signal detection units 44 and 45 may be provided such that control is performed on the basis of output signals of the output signal detection units 44 and 45.

In this case, the main amplifier output signal detection unit (first output signal detection unit) 44 for detecting an output signal of the first amplifier 40 and the peak amplifier output signal detection unit (second output signal detection unit) 45 for detecting an output signal of the peak amplifier 41 may be provided such that the output signal detection units 44 and 45 are coupled to the controller 3 and the controller 3 performs control for adjusting the flow rate of coolant to be supplied to the cooling plates 1 and 2 in the normal state or in the non-normal state on the basis of output signals detected by the output signal detection units 44 and 45.

Further, the controller 3 may control also operation of the main amplifier 40 and the peak amplifier 41.

Further, the controller 3 may decide whether or not the current state is the normal state or the non-normal state on the basis of an output signal of the cooling target 10. For example, the controller 3 may decide a state in which an output signal of the peak amplifier 41 included in the Doherty amplifier 10Y that is a cooling target 10 is not detected as the normal state but decide another state in which an output signal of the peak amplifier 41 is detected as the non-normal state.

Where the cooling apparatus 11 is configured in this manner, the controlling method therefor may be such as described below.

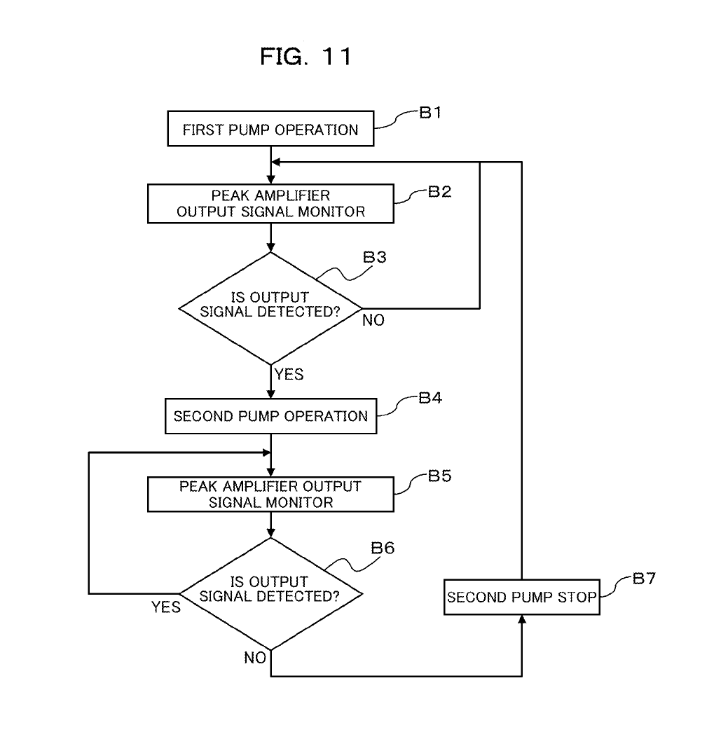

As depicted in FIG. 11, in the normal state, namely, in normal operation, the controller 3 performs control for operating the first pump 6 in an interlocking relationship with operation of the main amplifier 40 provided in the Doherty amplifier 10Y.

In particular, after the controller 3 renders the main amplifier 40 provided in the Doherty amplifier 10Y operative (here, if, while an output signal (signal output) of the main amplifier 40 detected by the main amplifier output signal detection unit 44 is monitored, an output signal of the main amplifier 40 is detected), the controller 3 controls the first power supply 20 to render the first pump 6 operative in an interlocking relationship with the detection.

Consequently, the coolant circulates through the first coolant supply pipe 4, first cooling plate 1, first coolant discharge pipe 8 and first heat exchanger 18, and cooling of the Doherty amplifier 10Y is performed only by the first cooling plate 1 (refer to FIG. 10).

Then, while the controller 3 monitors an output signal of the peak amplifier 41 detected by the peak amplifier output signal detection unit 45 built in the Doherty amplifier 10Y, it performs control of the entire cooling system (step B2 to step B7).

In particular, the controller 3 first monitors an output signal (signal output) of the peak amplifier 41 detected by the peak amplifier output signal detection unit 45 (step B2) and decides whether or not an output signal of the peak amplifier 41 is detected (step B3).

If it is decided as a result of the decision that an output signal of the peak amplifier 41 is not detected, namely, if it is decided that the peak amplifier 41 is not operative, then the processing advances to the NO route and the controller 3 continues the control for operating the first pump 6 while monitoring an output signal of the peak amplifier 41.

On the other hand, if it is decided that an output signal of the peak amplifier 41 is detected, namely, if it is decided that the peak amplifier 41 starts its operation, then the processing advances to the YES route and the controller 3 performs control for rendering the second pump 7 operative (step B4). In other words, the controller 3 controls the second power supply 21 to render the second pump 7 operative.

Consequently, the coolant circulates through the second coolant supply pipe 5, second cooling plate 2, second coolant discharge pipe 9 and second heat exchanger 19, and cooling of the Doherty amplifier 10Y is performed also by the second cooling plate 2 in addition to the first cooling plate 1 (FIG. 10). Consequently, heat generation of two amplifiers 40 and 41 can be cooled efficiently.

Then, the controller 3 monitors an output signal (signal output) of the peak amplifier 41 detected by the peak amplifier output signal detection unit 45 (step B5) and decides whether or not an output signal of the peak amplifier 41 is detected (step B6).

If it is decided as a result of the decision that an output signal of the peak amplifier 41 is detected, then the processing advances to the YES route and the controller 3 continues the control for operating the second pump 7 while monitoring an output signal of the peak amplifier 41.

On the other hand, if it is decided that an output signal of the peak amplifier 41 is not detected, namely, if an output signal of the peak amplifier 41 is detected no more, then the processing advances to the NO route and the controller 3 performs control for stopping the second pump 7 (step B7). Thereafter, the processing returns to step B2, and the controller 3 continues the control for operating the first pump 6 while monitoring an output signal of the peak amplifier 41.

It is to be noted that, after the main amplifier 40 is stopped (here, after an output signal of the main amplifier 40 becomes no more detected), the controller 3 performs control for stopping the first pump 6 in an interlocking relationship with the stopping of the main amplifier 40.

In this manner, only when the main amplifier 40 is operative, the first pump 6 is rendered operative to perform cooling only by the first cooling plate 1, and after the peak amplifier 41 starts its operation, also the second pump 7 is rendered operative, namely, both circulation pumps 6 and 7 are operated, to perform cooling using the second cooling plate 2 in addition to the first cooling plate 1. By this, a cooling performance can be secured.

It is to be noted that, although the present second modification is described taking a case in which a cooling apparatus having a configuration similar to that of the cooling apparatus of the embodiment described hereinabove as an example, the second modification is not limited to this. For example, also it is possible to use a cooling apparatus having a configuration similar to that of the cooling apparatus of the first medication described hereinabove (refer to FIG. 8), and also it is possible to use the single pump 32 and adjust the flow rate of the cooling plates 1 and 2 by the flow rate adjuster 30 similarly as in the case of the first modification described above.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling apparatus, comprising:
a first cooling plate;
a second cooling plate provided on the first cooling plate; and
a controller that performs, in a normal state, control for supplying coolant to the first cooling plate and performs, in a non-normal state other than the normal state, control for supplying the coolant to the first cooling plate and the second cooling plate.

2. The cooling apparatus according to claim 1, wherein an upper face of the first cooling plate and a lower face of the second cooling plate are joined together.

3. The cooling apparatus according to claim 1, wherein the controller decides whether the cooling apparatus is in the normal state or in the non-normal state based on a temperature of a cooling target and performs control in the normal state and control in the non-normal state based on a result of the decision.

4. The cooling apparatus according to claim 1, wherein the controller decides whether the cooling apparatus is in the normal state or in the non-normal state based on an output signal of a cooling target and performs control in the normal state and control in the non-normal state based on a result of the decision.

5. The cooling apparatus according to claim 1, further comprising:
a first coolant supply pipe coupled to the first cooling plate;
a second coolant supply pipe coupled to the second cooling plate;
a first pump provided for the first coolant supply pipe; and
a second pump provided for the second coolant supply pipe; wherein
the controller adjusts, in the normal state, a flow rate of the coolant to be supplied to the first cooling plate by controlling the first pump and adjusts, in the non-normal state, a flow rate of coolant to be supplied to the first cooling plate and the second cooling plate by controlling the first pump and the second pump.

6. The cooling apparatus according to claim 1, further comprising:
a first coolant supply pipe coupled to the first cooling plate;
a second coolant supply pipe coupled to the second cooling plate;
a flow rate adjuster coupled to the first coolant supply pipe and the second coolant supply pipe;
a third coolant supply pipe coupled to the flow rate adjuster; and
a pump provided for the third coolant supply pipe; wherein
the controller adjusts, in the normal state, a flow rate of the coolant to be supplied to the first cooling plate by controlling the pump and the flow rate adjuster and adjusts, in the non-normal state, a flow rate of the coolant to be supplied to the first cooling plate and the second cooling plate by controlling the pump and the flow rate adjuster.

7. The cooling apparatus according to claim 1, further comprising a heat insulating structure that insulates heat of the first cooling plate and the second cooling plate.

8. The cooling apparatus according to claim. 7, further comprising, as the heat insulating structure, a heat insulating material that covers the first cooling plate and the second cooling plate.

9. The cooling apparatus according to claim. 7, further comprising, as the heat insulating structure, a vacuum heat insulating structure that insulates heat by placing a periphery of the first cooling plate and the second cooling plate into a vacuum state.

10. The cooling apparatus according to claim 1, further comprising:
a first coolant supply pipe coupled to the first cooling plate;
a first coolant discharge pipe coupled to the first cooling plate;
a second coolant supply pipe coupled to the second cooling plate;
a second coolant discharge pipe coupled to the second cooling plate; and
a heat insulating structure that insulates heat of the first coolant supply pipe, first coolant discharge pipe, second coolant supply pipe and second coolant discharge pipe.

11. The cooling apparatus according to claim 10, further comprising, as the heat insulating structure, a heat insulating material that covers the first coolant supply pipe, first coolant discharge pipe, second coolant supply pipe and second coolant discharge pipe.

12. The cooling apparatus according to claim 10, wherein the first coolant supply pipe, first coolant discharge pipe, second coolant supply pipe and second coolant discharge pipe include a vacuum heat insulating structure as the heat insulating structure.

13. The cooling apparatus according to claim 1, further comprising:
a first coolant supply pipe coupled to the first cooling plate; and
a second coolant supply pipe coupled to the second cooling plate; wherein
the first cooling plate includes a slit-formed flow path and has the first coolant supply pipe coupled to a side face thereof; and
the second cooling plate includes a flow path having a pillar-formed projection and has the second coolant supply pipe coupled to an upper face thereof.

14. An exhaust gas processing apparatus, comprising:
a microwave generation source that processes fine particles included in exhaust gas; and
a cooling apparatus that cools the microwave generation source; wherein
the cooling apparatus includes:
a first cooling plate provided on the microwave generation source;
a second cooling plate provided on the first cooling plate; and
a controller that performs, in a normal state, control for supplying coolant to the first cooling plate and performs, in a non-normal state other than the normal state, control for supplying the coolant to the first cooling plate and the second cooling plate.

15. The exhaust gas processing apparatus according to claim 14, further comprising:
a temperature measurement unit provided on a microwave amplifier provided in the microwave generation source; wherein
the controller decides whether the cooling apparatus is in the normal state or in the non-normal state based on a temperature of the microwave amplifier measured by the temperature measurement unit and performs control in the normal state and control in the non-normal state based on a result of the decision.

16. The exhaust gas processing apparatus according to claim 14, further comprising a heat insulating structure that insulates heat of the first cooling plate and the second cooling plate.

17. The exhaust gas processing apparatus according to claim 14, further comprising:
a first coolant supply pipe coupled to the first cooling plate;
a first coolant discharge pipe coupled to the first cooling plate;
a second coolant supply pipe coupled to the second cooling plate;
a second coolant discharge pipe coupled to the second cooling plate; and
a heat insulating structure that insulates heat of the first coolant supply pipe, first coolant discharge pipe, second coolant supply pipe and second coolant discharge pipe.

18. A controlling method performed by a controller, comprising:
performing, in a normal state, control for supplying coolant to a first cooling plate; and
performing, in a non-normal state other than the normal state, control for supplying the coolant to the first cooling plate and a second cooling plate provided on the first cooling plate.

19. An electronic apparatus, comprising:
a microwave amplifier; and
a cooling apparatus that cools the microwave amplifier; wherein
the cooling apparatus includes:
a first cooling plate provided on the microwave amplifier;
a second cooling plate provided on the first cooling plate; and
a controller that performs, in a normal state, control for supplying coolant to the first cooling plate and performs, in a non-normal state other than the normal state, control for supplying the coolant to the first cooling plate and the second cooling plate.

20. The electronic apparatus according to claim 19, wherein the microwave amplifier includes a first amplifier and a second amplifier coupled in parallel to the first amplifier; and
the controller decides whether the cooling apparatus is in a normal state or in a non-normal state based on an output signal of the second amplifier provided for the microwave amplifier and performs control in the normal state and control in the non-normal state based on a result of the decision.
